(19) United States
(12) Patent Application Publication
(10) Pub. No.: US 2018/0132373 A1
(43) Pub. Date: May 10, 2018

(54) COVER ASSEMBLIES AND METHODS FOR MANUFACTURING THE SAME

(71) Applicant: AMETEK, INC., Berwyn, PA (US)

(72) Inventors: Charles M. Italiano, Ossining, NY (US); Thomas A. Bobal, Hamilton Square, NJ (US); Maurice P.C. Mevissen, Ridgewood, NJ (US)

(21) Appl. No.: 15/803,899

(22) Filed: Nov. 6, 2017

Related U.S. Application Data
(60) Provisional application No. 62/418,831, filed on Nov. 8, 2016.

(51) Int. Cl. H05K 5/06; H05K 5/03; H05K 5/04

(52) U.S. Cl. CPC H05K 5/069; H05K 5/04; H05K 5/03

(57) ABSTRACT

Aspects of the invention relate to cover assemblies and methods for manufacturing such cover assemblies. According to one aspect of the invention, a cover assembly is provided for hermetically sealing electronic circuitry. The cover assembly includes a cover having a frame connection surface. The frame connection surface has a periphery section extending along an outer portion of the frame connection surface. The cover assembly also includes a frame having an annulus shape and a cover connection surface and a package connection surface spaced from the cover connection surface. Additionally, the cover assembly includes a laser weld that couples the cover connection surface of the frame to the frame connection surface of the cover in the periphery section to form the cover assembly. The package connection surface of the frame is exposed for attachment to the substrate after the cover assembly is formed.

### CROSS REFERENCE TO RELATED APPLICATIONS

This application claims priority to and benefit of U.S. Provisional Patent Application No. 62/418,831, filed Nov. 8, 2016, the entire disclosure of which is incorporated herein by reference.

### FIELD OF THE INVENTION

The present invention relates to cover assemblies as well as methods and systems for manufacturing the same and, more particularly, to cover assemblies for hermetic sealing an electronic package.

### BACKGROUND OF THE INVENTION

The electronic packaging industry utilizes cover assemblies to form hermetically sealed electronic packages after the necessary electronic circuitry has been positioned inside the package. Worldwide usage of cover assemblies is generally predicted to be between 15 and 20 million on an annual basis.

Cover assemblies generally protect electronic circuitry from various risks of damage including environmental factors. The environmental sensitivity of certain modern electronic circuitry requires that the hermetic seal formed by cover assemblies be of the highest quality level.

Additionally, the large quantity of cover assemblies used on an annual basis requires that the cost per cover assembly be reasonable. Accordingly, there is a long felt need for high-quality cover assemblies that have a reasonable cost.

### SUMMARY OF THE INVENTION

Aspects of the invention relate to cover assemblies as well as methods and systems for manufacturing such cover assemblies.

In accordance with one aspect of the invention, a cover assembly is provided for hermetically sealing electronic circuitry. The cover assembly includes a cover having a frame connection surface. The frame connection surface has a periphery section extending along an outer portion of the frame connection surface. The cover assembly also includes a frame having an annulus shape and a cover connection surface and a package connection surface spaced from the cover connection surface. Additionally, the cover assembly includes a laser weld that couples the cover connection surface of the frame to the frame connection surface of the cover in the periphery section to form the cover assembly. The package connection surface of the frame is exposed for attachment to the substrate after the cover assembly is formed.

In accordance with another aspect of the invention, a ceramic cover assembly is provided for hermetically sealing an electronic package. The ceramic cover assembly including a ceramic cover having a frame connection surface, a frame, and a laser weld. The frame connection surface having a periphery section extending along an outer portion of the frame connection surface. The periphery section including a metalized layer. The frame having an annulus shape and including a cover connection surface spaced from a package connection surface. The laser weld coupling the cover connection surface of the frame to the periphery section of the frame connection surface of the ceramic cover to form the ceramic cover assembly. The package connection surface of the ceramic frame is exposed for attachment to an electronic package after the ceramic cover assembly is formed.

In accordance with a further aspect of the invention, a method of manufacturing a cover assembly configured for hermetically sealing an electronic circuitry. The method including the steps of acquiring a cover having a frame connection surface, the frame connection surface having a periphery section extending along an outer portion of the frame connection surface; acquiring a frame having an annulus shape and including a cover connection surface spaced from a package connection surface; positioning the frame with respect to the cover such that the cover connection surface of the frame is aligned with the periphery section of the frame connection surface; and laser welding the frame to the cover to produce a tack weld between the frame and the cover to form the cover assembly prior to attachment of the package connection surface to the substrate having the electronic circuitry.

### BRIEF DESCRIPTION OF THE DRAWINGS

The invention is best understood from the following detailed description when read in connection with the accompanying drawings, with like elements having the same reference numerals. In accordance with common practice, the various features of the drawings are not drawn to scale unless otherwise indicated. On the contrary, the dimensions of the various features may be expanded or reduced for clarity. Included in the drawings are the following figures:

FIG. 1 is a perspective view of a cover assembly in accordance with aspects of the invention;

FIG. 2 is bottom view of the cover assembly of FIG. 1;

FIG. 3 is a top view of the cover assembly of FIG. 1;

FIG. 4 is a side view of the cover assembly of FIG. 1 sealed to a substrate;

FIG. 5 is a front view of a cover of the cover assembly of FIG. 1;

FIG. 6 is a side view of the cover of FIG. 5;

FIG. 7 is a top view of the frame of FIG. 1;

FIG. 8 is a side view of the frame of FIG. 7;

FIG. 9 is a flow chart of a method for manufacturing cover assemblies according to an aspect of the invention; and

FIG. 10 is an image of an embodiment of a cover assembly in accordance with aspects of the invention.

### DETAILED DESCRIPTION OF THE INVENTION

Aspects of the invention provide high quality cover assemblies that may be manufactured at a reasonable cost, thereby solving the long felt need for high quality, reasonably priced cover assemblies.

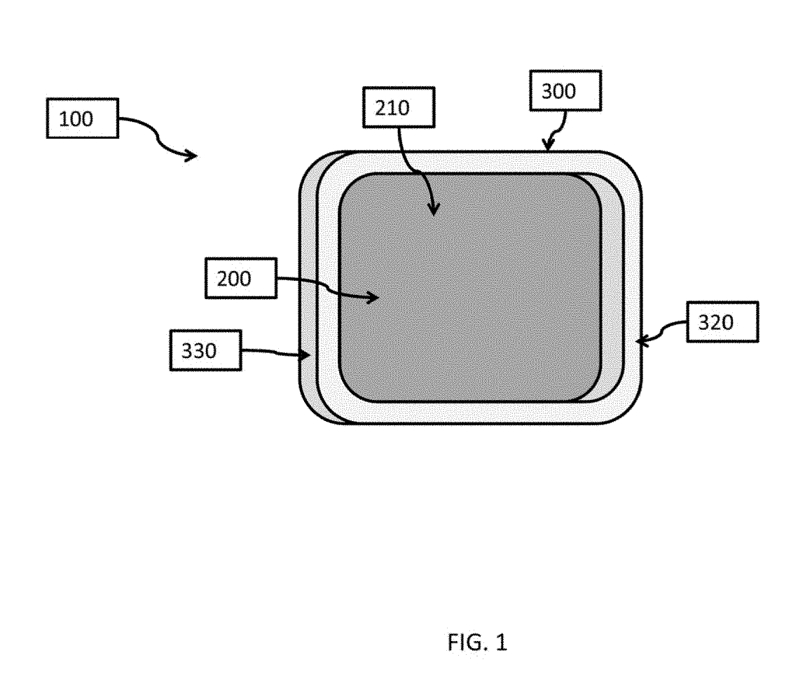

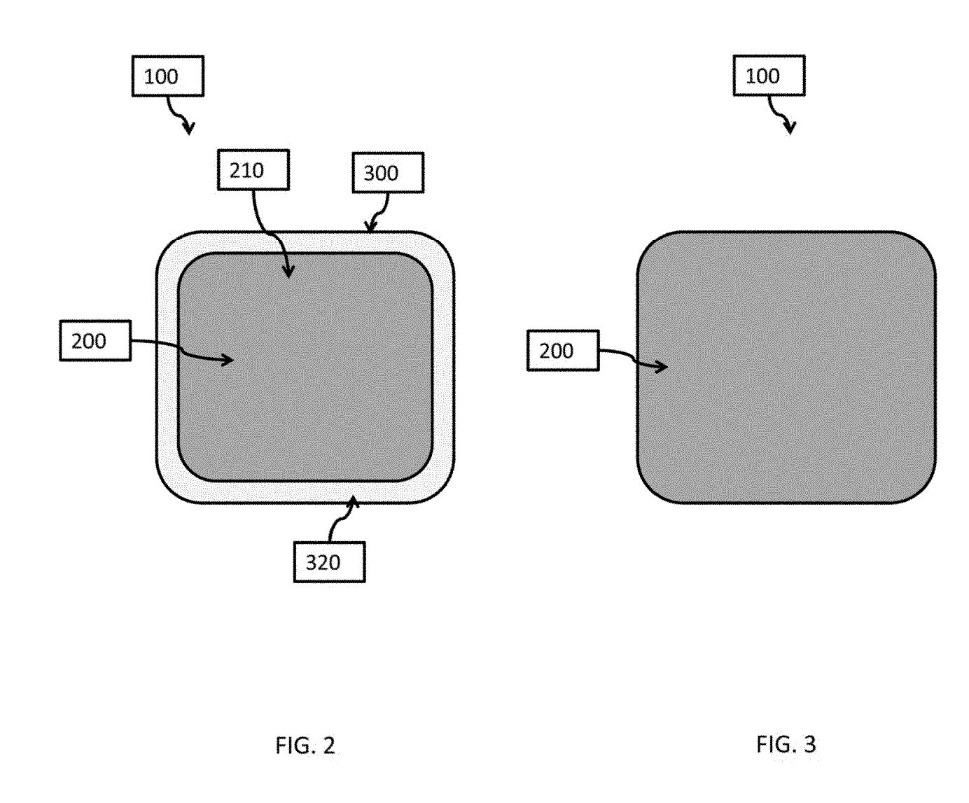

A cover assembly 100 is depicted in FIGS. 1-4. The cover assembly 100 is configured for attachment to a substrate 500 having electronic circuitry, e.g., to hermetically seal the electronic circuitry within to form an electronic package. Aspects of the invention include a cover assembly 100 that includes a cover 200 and a frame 300. In one embodiment, the cover assembly 100 consists solely of cover 200 and frame 300 and a weld(s) 400 therebetween. By using aspects of the invention, cover assemblies 100 may be manufactured using fewer parts; thus, costing less to produce. Additionally, using cover assembly 100, the frame 300 (with attached cover 200) may be positioned at a specific location on a substrate 500 needed to produce a high quality electrical package when the cover assembly 100 is attached to the substrate 500 to hermetically seal the electronic circuitry.

The cover 200 may be formed of a metallic material, a non-metallic material (e.g., a ceramic material), and/or a combination thereof. Suitable metallic materials for cover 200 include, but are not limited to: ferrous alloys such as, e.g., Kovar™, Invar™, stainless steel, cold-rolled steel, etc.; aluminum and aluminum alloys; titanium and titanium alloys; nickel and nickel alloys; cobalt and cobalt alloys; copper and copper alloys and composites; molybdenum and molybdenum alloys and composites; tungsten and tungsten alloys and composites. Suitable non-metallic materials for cover 200 include, e.g., aluminum oxide (alumina), zirconium oxide (zirconia), etc. Cover 200 may also be formed of metal matrix composites including, but not limited to, aluminum silicon carbide (AlSiC) and Glidcop™.

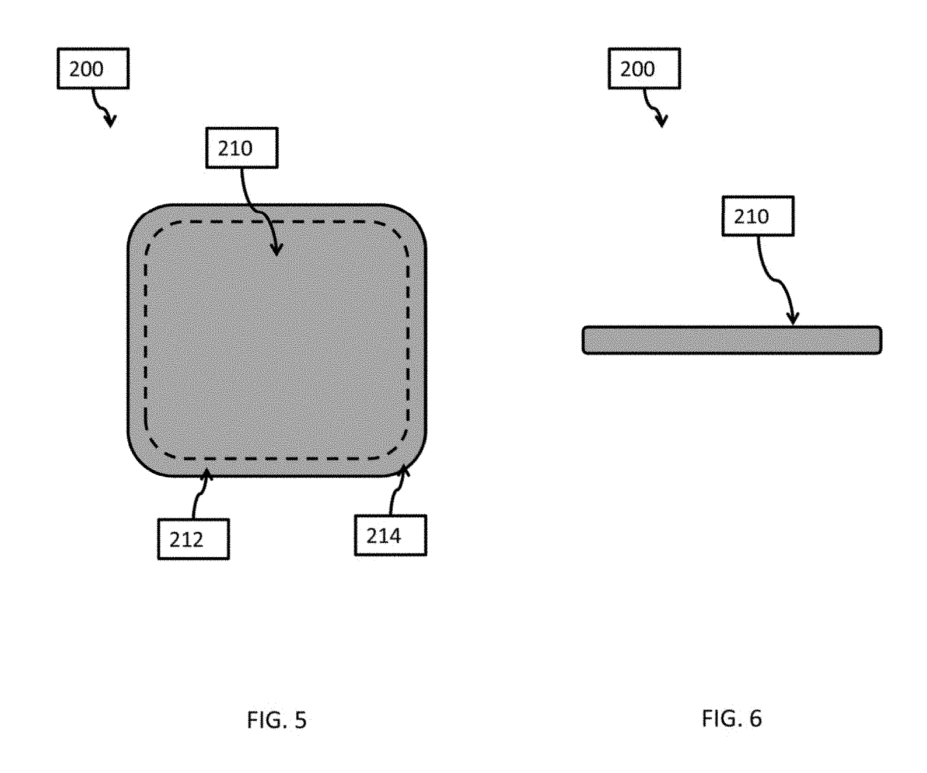

As illustrated in FIGS. 5-6, cover 200 includes a frame connection surface 210. Frame connection surface 210 of cover 200 is preferably smooth and/or substantially flat. In one embodiment, frame connection surface 210 extends along a plane with a less than 5% variation. In another embodiment, frame connection surface 210 varies with respect to a plane by less than 2%. Desirably, frame connection surface 210 is substantially free of dirt, debris, or other foreign substances. For example, nicks, dents, and/or scratches may be unacceptable for frame connection surface 210.

Cover 200 may have one or more metallized layers that extend along a base material surface of cover 200 to form frame connection surface 210 or a portion thereof. Preferably, the one or more metallized layers are compatible with soldering materials and processes. The one or more metallized layers may include an under-plate layer and an outer-plate layer. For example, in embodiments having a metal cover, the under-plate layer may be nickel (e.g., electrolytic nickel, an electroless nickel, nickel alloy, etc.) and the outer-plate layer may be gold. In one embodiment, the one or more metallized layers includes a first layer of nickel, followed by a second layer of gold, followed by a third layer of nickel, followed by a fourth layer of gold. Preferably, in embodiments having a metal cover, the under-plate layer comprising nickel has a thickness between 1.27 microns and 8.89 microns and the outer-plate layer comprising gold has a thickness of 0.635 microns or more. In embodiments having a non-metal cover, one or more metallized layers may be formed by a thin film process and/or a thick film process. For example, the thin film process may use an adhesion layer (e.g., titanium or chromium), followed by an under-plate (e.g., nickel), followed by an outer-plate (e.g., gold). In embodiments using thin film processes having three layers, each of the three layers have a thicknesses of about 1 micron or less. The thick film processes may use an adhesion layer (e.g., a moly-manganese layer), followed by an under-plate (e.g., a nickel layer), followed by an outer-plate (e.g., a gold layer). In embodiments using thick film processes having three layers, each of the three layers may have a thickness of about 1 micron to about 5 microns.

The one or more metalized layers may be disposed continuously along a surface of a base material of cover 200 such that, e.g., the base material of cover 200 is not exposed. In another embodiment, the one or more metallized layers are uniform in thickness. For example, the one or more metallized layers may have a thickness that varies by 5% or less, preferably by 2.5% or less, and more preferably by 1% or less.

Frame connection surface 210 has a periphery section 212 extending along an outer portion 214 of frame connection surface 210. In one embodiment, periphery section 212 is defined by the area of frame connection surface 210 that contacts frame 300. One or more metallized layers may be disposed on periphery section 212 and/or outer portion 214 of frame connection surface 210. In one embodiment, the one or more metallized layers are solely disposed on periphery section 212 and/or outer portion 214. One of ordinary skill in the art would recognize that periphery section 212 and/or outer portion 214 may be modified in accordance with the desired parameters for the electrical package without deviating from the scope and spirit of the present invention.

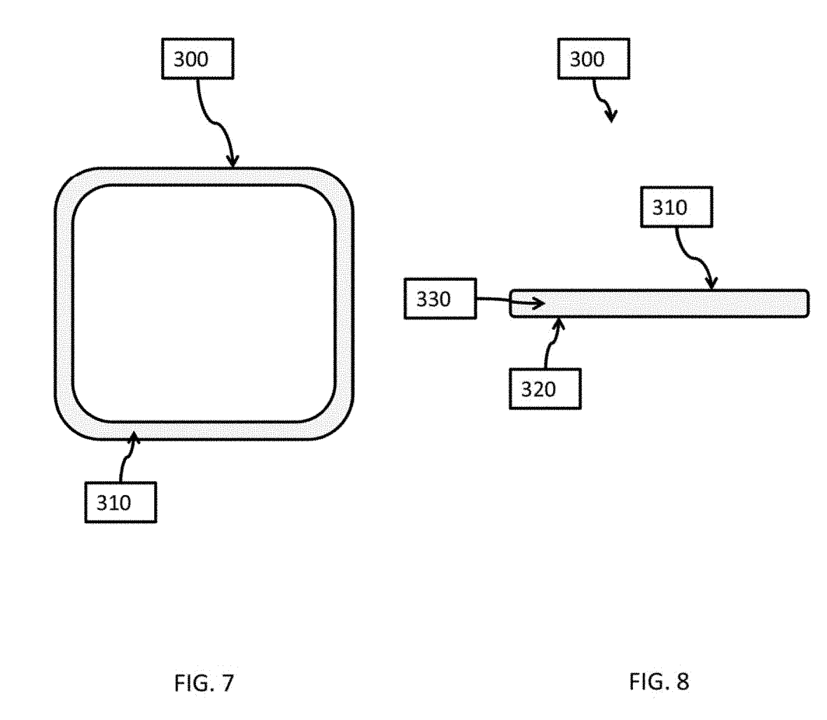

As illustrated in FIGS. 1-4, 7, and 8, cover assembly 100 also includes a frame 300. Frame 300 may be formed of metal. Frame 300 may be formed of any of the metallic materials described above with respect to cover 200. Additionally, and/or alternatively, frame 300 may be formed of materials including, but not limited to, gold-based solder alloys (e.g., gold-tin, gold-germanium, etc.); tin-based solder alloys (e.g., tin-silver, tin-silver-copper, etc.); Indium-based solder alloys (e.g., indium-silver, indium-tin, etc.); bismuth-based solder alloys (e.g., bismuth-tin); lead-based solder alloys (e.g., lead-silver-tin, lead-indium, etc.).

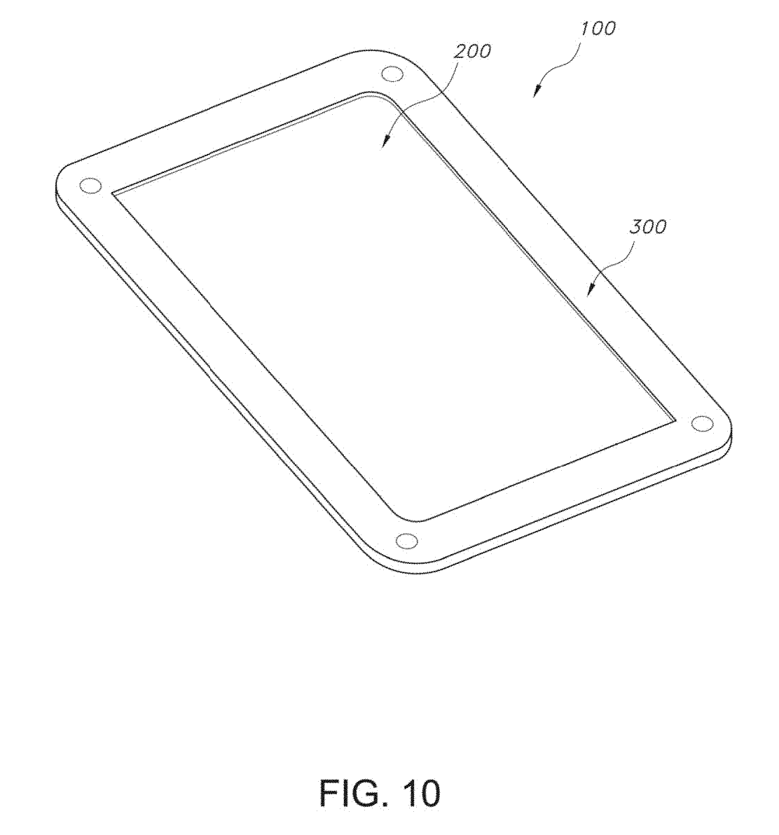

Frame 300 may have an annulus shape. The annulus shape of frame 300 may form a rectangular annulus shape. Although frame 300 is illustrated in FIGS. 1-4 and 10 as having a rectangular annulus shape, frame 300 may have any shape adapted to match or surround the desired electronic circuitry.

Frame 300 has a cover connection surface 310 and a package connection surface 320 spaced from the cover connection surface 310. Cover connection surface 310 is configured to be coupled to cover 200, e.g., by being affixed to periphery section 212 of frame connection surface 210. Package connection surface 320 may be configured for coupling to a surface of a substrate 500 that includes and/or is adapted to receive electronic circuitry. Preferably, package connection surface 320 of frame 300 is exposed for attachment to the surface of substrate 500 having electronic circuitry after cover assembly 100 is formed.

The cover connection surface 310 and/or the package connection surface 320 may be metalized to facilitate coupling to the frame and/or package. In one embodiment, however, frame 300 is formed of a homogenous metal, which does not receive one or more layers of metallization.

One or more layers of solder may be disposed between cover connection surface 310 of frame 300 and frame connection surface 210 of cover 200. Suitable materials for the solder layers include, but are not limited to, gold-based solder alloys (e.g., gold-tin, gold-germanium, etc.); tin-based solder alloys (e.g., tin-silver, tin-silver-copper, etc.); indium-based solder alloys, (e.g., indium-silver, indium-tin, etc.); bismuth-based solder alloys (e.g., bismuth-tin); and lead-based solder alloys (e.g., lead-silver-tin, lead-indium, etc.). One of ordinary skill in the art would recognize that the selection of solder materials may be optimized depending on various factors, such as melting temperature, environmental application, and cost.

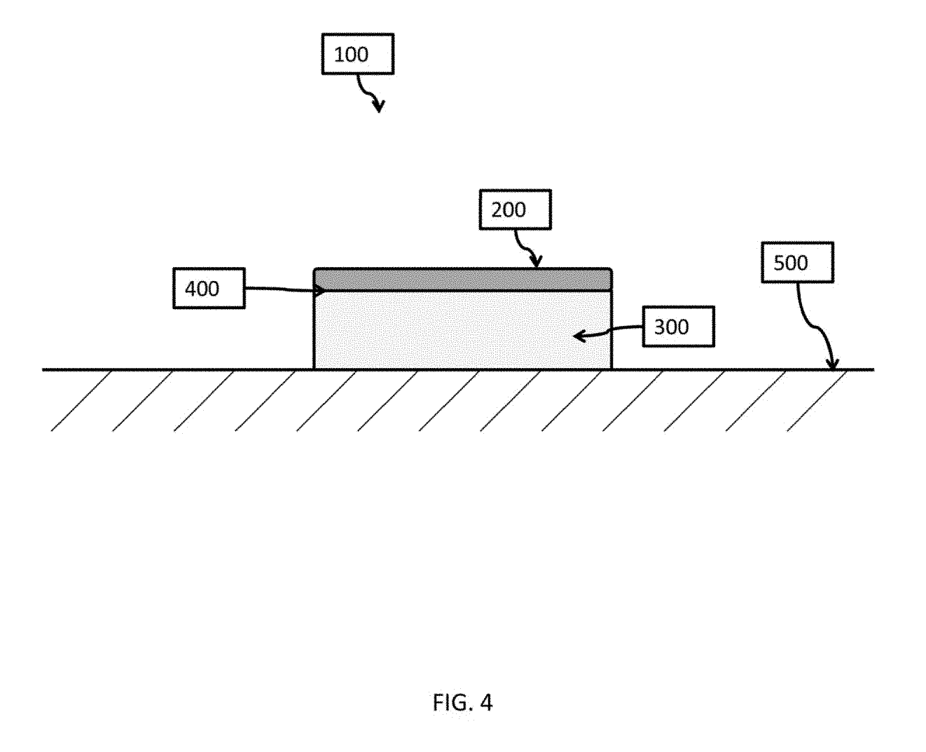

As illustrated in FIG. 4, cover assembly 100 includes a laser weld 400 coupling cover connection surface 310 of frame 300 to frame connection surface 210 of cover 200, e.g., at periphery section 212. The laser weld may include multiple spot welds (e.g., a weld at each of the four corners for a rectangular annulus shaped frame). The wavelength of the laser may be on the order of nanometers, thereby enabling the weld pattern of laser weld 400 to be small. In one embodiment, the weld pattern has a diameter of 0.005 inches. In another embodiment, laser weld 400 is formed between cover 200 and frame 300, wherein frame 300 has a thickness (e.g., a distance between the outer and inner side/periphery walls 330 of frame 300) that is 0.010 inches or less.

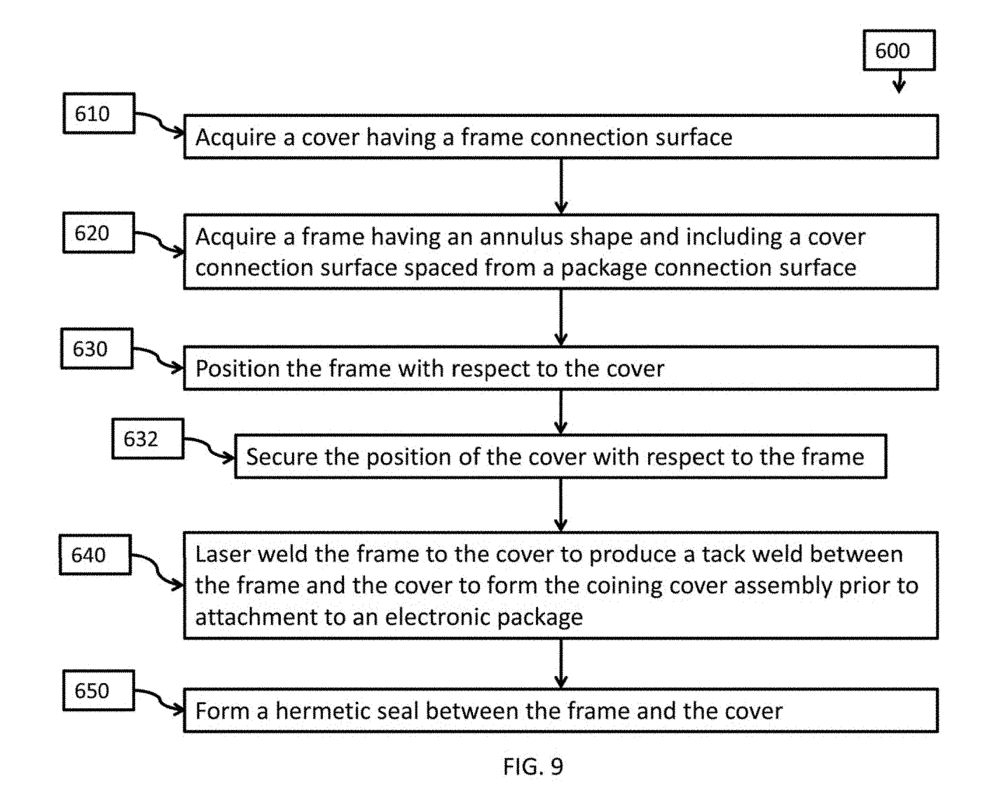

As illustrated in FIG. 9, a method is provided for manufacturing a cover assembly configured for coupling to an electronic package, e.g., to hermetically seal the electronic package.

Aspects of the present invention advantageously solve the problem of high levels of manual labor/input relating to rotating a lid and a fixture to a pre-specified location and conducting resisting welding, and repeating such process until all pre-specified locations are properly welded. The present invention includes methods that may utilize an automated robotic system to place a frame and a cover into a fixture. The fixture holds the lid and the frame in a position, such that the fixture aligns the lid and the frame, e.g., before and during tack welding so that the skew of the lid and the frame is within acceptable limits. In one embodiment, the acceptable limits for the skew of the lid and the frame is 3 mils or 0.003 inches. In one embodiment, the fixture travels to a second position where a laser beam is directed at the frame and a laser weld is accomplished. The nature of the laser allows the four pre-specified positions on the frame to be welded simultaneously. When the laser has completed the welds, a second robotic system removes the cover assembly from the fixture and places it into an appropriate package.

Using the systems, methods, and apparatuses disclosed herein, a system using robotic loading in conjunction with a laser system enables a 10× increase in cover assembly throughput over a manual system. This increase in throughput combined with reduced manual labor allows for a significantly lower cost, while maintaining high levels of quality.

In step 610, a cover having a frame connection surface is acquired. The frame connection surface has a periphery section extending along an outer portion of the frame connection surface. The cover may be acquired as a sheet of material and subsequently stamped. Additionally or alternatively, the cover may be acquired with a layer plating already disposed on the cover or may be acquired without a layer plating and/or stamping by coining.

In step 620, a frame having an annulus shape and including a cover connection surface spaced from a package connection surface is acquired. The frame may be acquired from sheet of solder material or may be acquired having the desired shape (e.g. an annulus shape). The frame may be cleaned to remove any dirt, debris, etc. The solder material may be dictated by a customer's specification. For example, the solder material may be an alloy having a 80%/20%, by weight respectively, of gold and tin. The frames may be subsequently stamped to meet the dimensional specification of the customer, which may be the same size as, e.g., an outer diameter of the cover.

In step 630, the frame is positioned with respect to the cover. Preferably, the frame and the cover are positioned with respect to each other such that the cover connection surface of the frame is aligned with the periphery section of the frame connection surface of the cover. In one embodiment, the positioning step includes aligning an edge of the frame to an edge of the cover. The positioning of the frame and the cover may be accomplished by a programmable robotic arm that is capable of precisely positioning the frame and/or the cover for laser welding. The programmable robotic arm may include a vacuum pickup tool for positioning the frame with respect to the cover. In one embodiment, the frame is moved and positioned with respect to cover. In another embodiment, the cover is moved and posited with respect to the frame.

In sub-step 632, a clamp may be employed to secure the position of the cover with respect to the frame. The clamps may be a weight, a spring, or any apparatus adapted to provide sufficient impetus or force to maintain contact between the frame and the cover, e.g., during welding.

In step 640, the frame is laser welded to the cover to produce a tack weld between the frame and the cover to form the cover assembly prior to attachment to a substrate having an electronic circuitry to form an electronic package. The laser weld may include spot welding at a plurality of spots. The laser welding is performed along a predefined pattern to produce a weld pattern. The weld pattern may produce a tack weld at each of the four corners of the frame. For example, the weld pattern may include a series of concentric circles at each of the four corners of the frame creating a molten puddle that attaches to the cover. In one embodiment, however, a single spot weld may be used.

The laser is applied at a predefined strength for a predefined duration. The strength and duration of the laser may be dependent on the thickness of the frames. For example, the laser's power may be between 10% and 90% with a duty cycle of between 20 and 100%.

In step 650, a hermetic seal may be formed between the frame and the cover by heating the cover assembly, e.g., at the end user's facility. For example, the cover assembly may be heated to a temperature under inert, reduced pressure, or vacuum conditions to reflow the frame material onto the surfaces of the cover and the substrate having the electronic circuitry to form an electrical package having a continuous hermetic seal around the perimeter of the electronic circuitry. In one embodiment, the hermetic seal extends along the entire periphery section of the cover.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A cover assembly for attachment to a substrate having electronic circuitry to hermetically seal the electronic circuitry, the cover assembly comprising:
a cover having a frame connection surface, the frame connection surface having a periphery section extending along an outer portion of the frame connection surface;
a frame having an annulus shape and including a cover connection surface and a package connection surface spaced from the cover connection surface; and
a laser weld coupling the cover connection surface of the frame to the frame connection surface of the cover in the periphery section to form the cover assembly,
wherein the package connection surface of the frame is exposed for attachment to the substrate after the cover assembly is formed.

2. The cover assembly of claim 1, wherein the cover is metal.

3. The cover assembly of claim 1, wherein the cover includes a ceramic cover portion with a metalized region in at least a portion of the periphery section.

4. The cover assembly of claim 1, wherein the frame is metal.

5. The cover assembly of claim 1, wherein the laser weld is a plurality of spot welds.

6. The cover assembly of claim 1, wherein the annulus shape is a rectangular annulus shape.

7. A ceramic cover assembly adapted for attachment to a substrate having an electronic circuitry to hermetically seal the electronic circuitry, the ceramic cover assembly comprising:
a ceramic cover having a frame connection surface, the frame connection surface having a periphery section extending along an outer portion of the frame connection surface, the periphery section including a metalized layer;
a frame having an annulus shape and including a cover connection surface spaced from a package connection surface; and
a laser weld coupling the cover connection surface of the frame to the periphery section of the frame connection surface of the ceramic cover to form the ceramic cover assembly,
wherein the package connection surface of the ceramic frame is exposed for attachment to the substrate after the ceramic cover assembly is formed.

8. The ceramic cover assembly of claim 7, wherein the frame is ceramic and includes a metalized region having at least one metalized layer disposed thereon.

9. A method of manufacturing a cover assembly configured for coupling to a substrate having an electronic circuitry to hermetically seal the electronic circuitry, the method comprising:
acquiring a cover having a frame connection surface, the frame connection surface having a periphery section extending along an outer portion of the frame connection surface;
acquiring a frame having an annulus shape and including a cover connection surface spaced from a package connection surface;
positioning the frame with respect to the cover such that the cover connection surface of the frame is aligned with the periphery section of the frame connection surface; and
laser welding the frame to the cover to produce a tack weld between the frame and the cover to form the cover assembly prior to attachment of the package connection surface to the substrate having the electronic circuitry.

10. The method of claim 9, wherein the positioning step further comprises aligning an edge of the frame to an edge of the cover.

11. The method of claim 9, wherein the step of laser welding further comprises spot welding at a plurality of spots.

12. The method of claim 9, wherein the annulus shape is a rectangular annulus shape having four corners.

13. The method of claim 12, wherein the laser welding is performed along a predefined pattern to produce a weld pattern, the weld pattern producing the tack weld at each of the four corners of the frame.

14. The method of claim 9, wherein the laser is provided at a predefined strength and for a predefined duration.

15. The method of claim 9, wherein the positioning step is performed by a robotic device.

16. The method of claim 9, further comprising producing a hermetic seal between the frame and the cover by heating the cover assembly.

17. The method of claim 16, wherein the hermetic seal extends along the entire periphery section.

18. The method of claim 16, wherein the hermetic seal is produced by reflow soldering.
